(19) United States
(12) Patent Application Publication
(10) Pub. No.: US 2025/0283241 A1
(43) Pub. Date: Sep. 11, 2025

(54) RESISTANCE CHANGE MEMORY AND METHOD FOR MANUFACTURING SAME

(71) Applicant: Research &Business Foundation SUNGKYUNKWAN UNIVERSITY, Suwon-si (KR)

(72) Inventors: Hyung Kyoun CHO, Yongin-si (KR); Dong Su KIM, Yongin-si (KR); Kun Woong LEE, Hwaseong-si (KR); Hak Hyeon LEE, Suwon-si (KR); Shin Young OH, Yongin-si (KR)

(21) Appl. No.: 19/070,766

(22) Filed: Mar. 5, 2025

(30) Foreign Application Priority Data
Mar. 7, 2024 (KR) 10-2024-0032412

(51) Int. Cl. C25D 15/00; C23C 14/30; C23C 28/00; G11C 13/00

(52) U.S. Cl. CPC C25D 15/00; C23C 14/30; C23C 28/32; C23C 28/345; G11C 13/0002

(57) ABSTRACT

An embodiment of the disclosure provides a method for manufacturing a resistance change memory, the method including forming an active layer between a lower electrode and an upper electrode, wherein the active layer includes a metal oxide thin film and metal nanoparticles, and the forming of the active layer is performed by an electrochemical reaction process.

### BACKGROUND

The disclosure relates to a resistance change memory and a method for manufacturing the same, and more particularly, to a resistance change memory including an active layer in which multiple conductive filaments are uniformly formed through an electrochemical pulse deposition process, and a method for manufacturing the same.

The performance of conventional artificial synapses, including resistance change memories, varies depending on the mechanism of forming conductive filaments between upper and lower electrodes. They are broadly divided into types in which conductive filaments of several nanometers in length are formed and local interface types.

Among them, the filament type has the advantages of superior durability, fast switching speed, and low energy consumption, unlike the local interface type. In particular, when driven by a single strong filament, the lateral movement of the conductive filament is implemented to delay the generation/annihilation along the vertical direction, thereby implementing analog switching. In the case of this type, the on/off switching ratio is excellent because the resistance value change is dynamic, but it is difficult to re-form conductive filaments at a uniform location, so stability and durability are low. In addition, there is a limit to implementing analog switching due to the rapid change in conductivity.

In addition, when multiple weak filaments are formed in the active layer, each conductive filament contributes to the overall conductivity change, so it is excellent for implementing analog switching, and since resistance changes occur in local filaments within the active layer, it has the advantages of fast driving speed and low current driving.

However, since each filament is randomly formed by the applied voltage, it is difficult to individually control the width and spacing, so there is a limit to securing the reproducibility of each filament. Therefore, there is a problem in storing a finely tuned resistance state due to long-term driving and vulnerability to noise signals.

On the other hand, in the case of the local interface type, defects are accumulated and driven throughout the interface between an electrode and an active layer. It is possible to implement analog switching, and this has high precision, and shows excellent linearity because it grows to the interface. However, unlike the filament type, it has very poor durability and stability, and has a considerably slow switching speed.

Therefore, the conductive type in the active layer of the conventional resistance change memory has limitations in possessing all the characteristics required for an ideal synaptic device, such as analog switching implementation, linearity, dynamic range, and endurance precision.

Most of the conventional technologies have performed single-level operation through a single filament, and multi-level operation was performed through the characteristics of the material to realize multi-filaments. Since there are limitations in controlling the material, there are also limitations in realizing multi-filaments.

### RELATED ART DOCUMENT

### Patent Document

Republic of Korea Patent Registration No. 10-1735406

### SUMMARY

An aspect of the disclosure is to provide a memory device capable of excellent analog operation by forming conductive filaments of uniform size at multiple fixed locations to reduce uncertainty and to compensate for the shortcomings of an interface type and a filament type.

The aspect of the disclosure is not limited to that mentioned above, and other aspects not mentioned will be clearly understood by those skilled in the art from the description below.

An embodiment of the disclosure provides a method for manufacturing a resistance change memory.

The method for manufacturing a resistance change memory according to an embodiment of the disclosure may include forming an active layer between a lower electrode and an upper electrode, wherein the active layer includes a metal oxide thin film and metal nanoparticles, and the forming of the active layer is performed by an electrochemical reaction process.

In addition, according to an embodiment of the disclosure, in the forming of the active layer, the active layer may be formed so that multiple conductive filaments are uniformly formed through an electrochemical pulse deposition process.

In addition, according to an embodiment of the disclosure, the forming of the active layer may include: forming a first metal oxide thin film layer; forming a metal nanoparticle layer on the formed first metal oxide thin film layer; and forming a second metal oxide thin film layer on the formed metal nanoparticle layer.

In addition, according to an embodiment of the disclosure, the forming of the first metal oxide thin film layer may include: impregnating the lower electrode in a solution including a metal oxide precursor and an electrolyte; and applying a first voltage to the solution.

In addition, according to an embodiment of the disclosure, the forming of the metal nanoparticle layer may be performed, after the applying of the first voltage, by applying a second voltage to the solution.

In addition, according to an embodiment of the disclosure, the forming of the second metal oxide thin film layer may be performed, after the applying of the second voltage, by applying a third voltage to the solution.

In addition, according to an embodiment of the disclosure, in the applying of the first voltage, a voltage of −0.5 V to −0.2 V may be applied.

In addition, according to an embodiment of the disclosure, in the applying of the second voltage, a voltage of less than −0.5V may be applied.

In addition, according to an embodiment of the disclosure, in the applying of the third voltage, a voltage of −0.5 V to −0.2 V may be applied.

In addition, according to an embodiment of the disclosure, the metal oxide thin film and metal nanoparticles may be composed of at least one metal selected from the group consisting of Cu, Ti, Zr, Pb, Mn, Bi, Al, Sb, Fe, Co, Nb, and Cr.

In addition, according to an embodiment of the disclosure, the method may further include, after the forming of the active layer, forming an upper electrode on the formed active layer.

In addition, according to an embodiment of the disclosure, the forming of the upper electrode may be performed through an electron beam deposition process with an electrode precursor input.

Another embodiment of the disclosure provides a resistance change memory.

The resistance change memory according to an embodiment of the disclosure, which is manufactured according to the method described above, may include: a lower electrode; an active layer positioned on the lower electrode; and an upper electrode positioned on the active layer, wherein the active layer has multiple conductive filaments uniformly formed.

In addition, according to an embodiment of the disclosure, the active layer may include: a first metal oxide thin film layer; a metal nanoparticle layer positioned on the first metal oxide thin film layer; and a second metal oxide thin film layer positioned on the metal nanoparticle layer.

In addition, according to an embodiment of the disclosure, the metal nanoparticle layer may include metal nanoparticles having diameters of 10 nm to 100 nm.

According to an embodiment of the disclosure, a resistance change memory including an active layer in which multiple conductive filaments are uniformly formed through an electrochemical pulse deposition process and a manufacturing method thereof can be provided.

According to an embodiment of the disclosure, conductive filaments of uniform size are formed at multiple fixed locations to reduce uncertainty, thereby compensating for the shortcomings of an interface type and a filament type and providing a memory device capable of excellent analog operation.

According to an embodiment of the disclosure, since a metal oxide thin film layer and a metal nanoparticle layer constituting an active layer are formed by causing an electrochemical reaction rather than physically or chemically growing them, thickness control in a nano-unit is possible, and electrical characteristics can be adjusted by forming a uniform thin film over the entire device.

According to an embodiment of the disclosure, an active layer capable of multiple conductive filaments is provided through the growth of a metal oxide thin film and metal nanoparticles, and through this, uniformity and multiplicity can be satisfied at the same time, and individually operable filament-type behavior that enables gradual analog switching and synaptic operation can be induced.

According to an embodiment of the disclosure, a formation region of a conductive filament can be fixed from the stage before the formation of the conductive filament when a resistance change is driven by metal nanoparticles grown through electrochemical pulse deposition, and a process of generating the conductive filament can be confirmed as an in-situ process.

In addition, most of the existing studies grow an active layer through a physical vapor deposition process including an atomic layer thin film process, so expensive equipment is required to control high temperature and vacuum conditions; however, the growth of an active layer through an electrochemical method according to an embodiment of the disclosure can significantly reduce the process cost because low-cost equipment is used.

The effects of the disclosure are not limited to the effects described above, and should be understood to include all effects that are inferable from the configuration of the disclosure described in the detailed description or claims of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flow chart of a method for manufacturing a resistance change memory according to an embodiment of the disclosure;

FIG. 2 is a cross-sectional view schematically showing the structure of a resistance change memory according to an embodiment of the disclosure;

FIGS. 3A and 3B are graphs showing electrochemical data for the formation of a metal oxide thin film and metal nanoparticles constituting an active layer in a resistance change memory according to an embodiment of the disclosure;

FIGS. 4A, 4B, and 4C are electrical current-voltage graphs according to the active layer structure of a resistance change memory according to an embodiment of the disclosure;

FIGS. 5A, 5B, 5C, and 5D are microscopic analysis images according to the amount of Cu nanoparticles in manufacturing a resistance change memory according to an embodiment of the disclosure; and

FIGS. 6A, 6B, 6C, 6D, 6E, and 6F are graphs showing the results of evaluating the synaptic device characteristics of a resistance change memory according to an embodiment of the disclosure.

### DETAILED DESCRIPTION

Hereinafter, the disclosure will be described with reference to the accompanying drawings. However, the disclosure may be implemented in various different forms and therefore is not limited to the embodiments described herein, but should be understood to include all modifications, equivalents, or substitutes included in the spirit and technical scope of the disclosure.

In addition, in order to clearly describe the disclosure in the drawings, parts that are not related to the description are omitted, and similar parts are given similar drawing reference numerals throughout the specification.

In the entire specification, when a part is said to be “connected (linked, contacted, coupled)” to another part, this includes not only the case where it is “directly connected” but also the case where it is “indirectly connected” with another member in between.

In addition, when a part such as a layer, film, region, or plate is said to be “on” another part, this includes not only the case where it is “directly on” another part, but also the case where there is another part in between. In addition, in this specification, when a part such as a layer, film, region, or plate is formed on another part, the direction in which it is formed is not limited to the upper direction, and includes being formed in the side or lower direction. On the other hand, when a part such as a layer, film, region, or plate is said to be “under” another part, this includes not only the case where it is “directly under” another part, but also the case where there is another part in between.

In this specification, the terms “upper surface” and “lower surface” are used as relative concepts in order to easily explain the technical idea of the disclosure. Therefore, the terms “upper surface” and “lower surface” do not refer to a specific direction, position, or component, and are interchangeable with each other.

For example, the “upper surface” may be interpreted as the “lower surface,” and the “lower surface” may be interpreted as the “upper surface.” Therefore, the “upper surface” may be expressed as “first” and the “lower surface” may be expressed as “second”, or the “lower surface” may be expressed as “first” and the “upper surface” may be expressed as “second”. However, within one embodiment, the terms “upper surface” and “lower surface” are not used interchangeably.

Unless otherwise defined, all terms used herein, including technical or scientific terms, have the same meaning as generally understood by a person of ordinary skill in the art to which the disclosure belongs. Terms defined in commonly used dictionaries should be interpreted as having a meaning consistent with the meaning they have in the context of the relevant technology, and shall not be interpreted in an ideal or overly formal sense unless explicitly defined in this application.

In addition, when a part is said to “include” a certain component, this does not exclude other components unless specifically stated to the contrary, but rather means that other components may be additionally provided.

The terms used in this specification are used only to describe specific embodiments and are not intended to limit the disclosure. The singular expression includes the plural expression unless the context clearly indicates otherwise. In this specification, the terms “include” or “have” are intended to specify the presence of a feature, number, step, operation, component, part, or combination thereof described in the specification, but should be understood as not excluding in advance the possibility of the presence or addition of one or more other features, numbers, steps, operations, components, parts, or combinations thereof.

Hereinafter, embodiments of the disclosure will be described in detail with reference to the accompanying drawings.

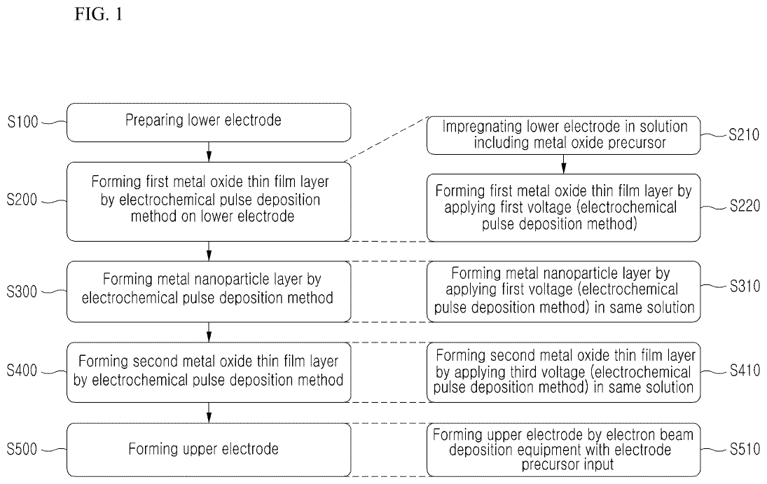

FIG. 1 is a flow chart of a method for manufacturing a resistance change memory according to an embodiment of the disclosure.

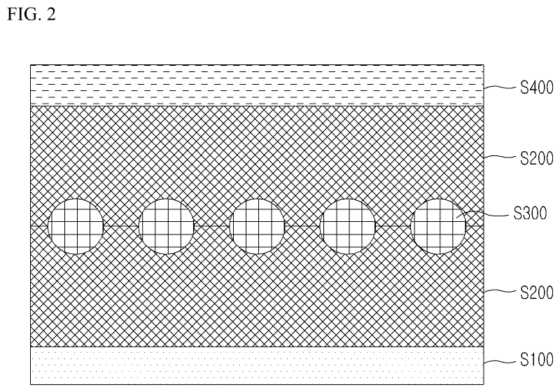

FIG. 2 is a cross-sectional view schematically showing the structure of a resistance change memory according to an embodiment of the disclosure.

Referring to FIGS. 1 and 2, a method for manufacturing a resistance change memory according to an embodiment of the disclosure will be described.

As an example of the embodiment, there may be a method for manufacturing a resistance change memory, the method including forming an active layer between a lower electrode and an upper electrode, wherein the active layer includes a metal oxide thin film and metal nanoparticles, and the forming of the active layer is performed by an electrochemical reaction process.

As an example of the embodiment, in the forming of the active layer, the active layer may be formed so that multiple conductive filaments are uniformly formed through an electrochemical pulse deposition process.

Referring to FIG. 1, it is possible to confirm that first, a lower electrode is provided (S100), then an active layer is formed through an electrochemical pulse deposition process (S200 to S400) so that multiple conductive filaments are uniformly formed, and finally an upper electrode is formed (S500).

The forming of the active layer may include:
forming a first metal oxide thin film layer; forming a metal nanoparticle layer on the formed first metal oxide thin film layer; and forming a second metal oxide thin film layer on the formed metal nanoparticle layer.

As can be seen in FIG. 1, electrochemical pulse deposition may be utilized to form the metal oxide semiconductor required for the active layer, and
based on this, metal nanoparticles that grow preferentially in a conductive region may be concentrated in an external electric field and used as a path for conductive filaments for analog resistance switching.

As described above, when forming the active layer through an electrochemical pulse deposition process, conductive filaments of uniform size are formed in multiple fixed locations, thereby reducing uncertainty, thereby complementing the shortcomings of an interface type and a filament type, and manufacturing a memory device capable of excellent analog operation.

As an example of the embodiment, the forming of the first metal oxide thin film layer may include: impregnating the lower electrode in a solution including a metal oxide precursor and an electrolyte; and applying a first voltage to the solution.

Referring to FIG. 1, it is possible to confirm that the forming of the first metal oxide thin film layer may include impregnating the lower electrode in a solution including a metal oxide precursor (S210), and then applying a first voltage to form the first metal oxide thin film layer through an electrochemical pulse deposition process (S220).

As an example of the embodiment, the forming of the metal nanoparticle layer may be performed, after the applying of the first voltage (S220), by applying a second voltage to the solution (S310).

As an example of the embodiment, the forming of the second metal oxide thin film layer may be performed, after the applying of the second voltage (S310), by applying a third voltage to the solution (S410).

The above-described electrochemical pulse deposition process may be performed by controlling the voltage and time applied to a metal material under an electrolyte, wherein
not only can the growth of the metal oxide thin film and the growth of the metal nanoparticles be induced and controlled by controlling the applied voltage and applied time,
but there is also an advantage in that the thickness can be controlled in the nano-unit and the electrical characteristics can be controlled by forming a uniform thin film over the entire device since the metal oxide thin film and metal nanoparticles constituting the active layer are formed by an electrochemical reaction rather than a scheme of physically or chemically growing them.

At this time, electrons required for the electrochemical growth are provided through the applied voltage, and hydroxide ions are provided through an electrolyte.

As an example of the embodiment, through the electrochemical pulse deposition method, the active layer may be formed to have a thickness range of 600 nm or less (=total thickness range of the first metal oxide thin film layer, the metal nanoparticle layer, and the second metal oxide thin film layer), and
in addition, the metal nanoparticle layer includes metal nanoparticles having a diameter of 10 nm to 100 nm, and may be formed between the first metal oxide thin film layer and the second metal oxide thin film layer to realize a multi-filament capable of resistive switching operation.

At this time, the metal nanoparticle layer does not have to be formed in the form of a film or thin film, and may be more preferable to be deposited in the form of particles rather than in the form of a thin film. In addition, it may refer to the region itself where the metal nanoparticles are distributed and present.

Therefore, in the resistance change memory according to an example of the embodiment,
the active layer may be a structure in which a region where a large number of the metal nanoparticles are distributed exists inside the metal oxide thin film layer (referring to both the first metal oxide thin film layer and the second metal oxide thin film layer).

At this time, in order for the metal nanoparticles to exist inside the metal oxide thin film layer, the active layer must basically be formed with a thickness greater than the diameter of the metal nanoparticles.

When the thickness of the active layer exceeds 600 nm, a conductive filament is formed and the charge transfer path from the upper/lower electrode to the lower/upper electrode becomes longer, so a high applied voltage is required. This poses a challenge to reasonable memory device performance targeting low power operation and low applied voltage.

In addition, as described above, in order for the metal nanoparticles to exist inside the metal oxide thin film layer, the active layer must basically be formed with a thickness greater than the diameter of the metal nanoparticles.

If the diameter of the metal nanoparticles is less than 10 nm, there is a problem that the conductive filaments do not have a uniform spherical shape but exist as irregularly shaped nanoparticles.

On the other hand, even if the diameter of the metal nanoparticles exceeds the critical point of 100 nm, irregularly shaped nanoparticles are generated and a gap between the metal nanoparticles is very narrow, which causes problems of interference between particles in the formation of conductive filaments and charge behavior.

In addition, if the diameter of the metal nanoparticles exceeds 100 nm, overlap occurs between the metal nanoparticles, and they grow in the form of a metal thin film rather than a particle form, which leads to a result contrary to the purpose of the disclosure to form multiple strong filaments.

In this case, the electrochemical pulse application time and the applied voltage must be set as critical conditions for growth to 100 nm in the form of metal nanoparticles in order to grow metal nanoparticles capable of forming strong multiple filaments, which is the aspect of the disclosure.

In contrast to the above, when the diameter of the metal nanoparticles has a thickness range of 10 nm to 100 nm, the conductive filament has a uniform spherical shape, and a gap between the first and second metal oxide thin film layers formed by each metal nanoparticle having the above diameter range has an advantage of having a shape suitable for realizing multiple filaments.

At this time, for the conductive filament configuration, sub-layer metal nanoparticles formed between the metal oxide thin film layers also have the advantage of being able to control the size and density of the particles by utilizing an electrochemical reaction, and securing an electrically advantageous conduction path.

At this time, the applying of the first voltage may apply a voltage of −0.5 V to −0.2 V,
the applying of the second voltage may apply a voltage of less than −0.5 V, and the applying of the third voltage may apply a voltage of −0.5 V to −0.2 V.

Likewise, in the electrochemical deposition process, the oxidation/reduction reaction between the electrode and the electrolyte may be controlled by changing the applied voltage within an electrolyte, and various transition metal-based materials may be formed through this.

As described above, the active layer was formed by continuously applying a voltage that may form a phase of the metal oxide thin film and metal nanoparticles constituting the active layer.

At this time, each step of applying the voltage is very important because the composition of the layer formed varies depending on the voltage range applied.

For example, when inducing an oxidation/reduction reaction in an electrolyte containing a metal precursor, a divalent metal ion is reduced to a monovalent metal ion when a voltage is applied in the potential range of −0.2 to −0.5 V.

On the other hand, in a potential range below-0.5 V, a divalent metal ion is immediately reduced to a metal.

That is, when the applied voltage has a potential range of −0.2 to −0.5 V, a metal oxide layer is deposited, and
when the applied voltage has a potential range of less than −0.5 V, a metal nanoparticle layer is deposited.

Likewise, it is possible to confirm that the metal thin film and the metal nanoparticles each have independent deposition potentials.

The first voltage range and the second voltage range are applied voltages required to grow the metal oxide thin film layer and the metal nanoparticles in the electrolyte that controls the pH by controlling OH⁻. Each applied voltage range is an applied range suitable for growing the Cu₂O thin film layer and the Cu metal particles.

When the first voltage range exceeds −0.2 V, a problem may occur in which a previously unexpected CuO thin film layer grows instead of the growth of the Cu₂O thin film layer,
and on the contrary, when it is less than −0.5 V, a problem in which the Cu metal can grow may occur.

When the second voltage range exceeds −0.5 V, the metal oxide thin film layer including CuO and Cu₂O may be grown because it corresponds to the above first voltage range.

Therefore, in the above electrochemical deposition process, the applied voltage, pH, and applied time must be controlled for selective synthesis of the desired material.

A more detailed explanation will be given in experimental examples below.

As an example of the embodiment, the metal oxide thin film and metal nanoparticles may be composed of at least one metal selected from the group consisting of Cu, Ti, Zr, Pb, Mn, Bi, Al, Sb, Fe, Co, Nb, and Cr.

As an example of the embodiment, in the case of the embodiment, this may be applied to various materials constituting the active layer in the resistance change memory, wherein
most active layer materials and conductive filament materials contain transition metals, and if the transition metal is applied using the electrochemical pulse deposition method and the sub-layer method, it is possible to drive an ideal synaptic device.

Compared to the realization of multi-filaments through conventional material control, in the case of the above embodiment, since multi-filaments are realized through electrochemical pulse deposition process control, conductive filaments can be efficiently controlled.

Therefore, through the technology, it is possible to control multi-conductive filaments and implement an ideal multi-level.

In the case of the metal oxide thin film formed of the above-mentioned metal, in addition to Cu₂O(I), there may also be transition metal-based oxide semiconductor devices (TiO₂, ZrO₂, PbO₂, MnO₂, Bi₂O₃, Al₂O₃, Sb₂O₃, Fe₂O₃, Co₃O₄, Nb:SrTiO₃, Cr:SrTiO₃) generated by an electrochemical reaction utilizing hydroxide ions and charges, and chalcogen compounds including selenium (Se) and sulfur (S).

By driving the multi-conductive filaments through the electrochemical deposition method according to the embodiment, the analog switching drive, wide dynamic range and linearity, long-term stability and precision, and retention characteristics of the device can be improved, and excellent memristive artificial synapse function can be secured.

In addition, the resistive memory device proposed through the disclosure has the advantages of excellent gradual analog switching, excellent linearity, dynamic range, durability, precision, speed, and retention characteristics for neuromorphic computing.

As an example of the embodiment, the method for manufacturing a resistance change memory may further include, after the forming of the active layer, forming an upper electrode on the formed active layer.

In addition, the forming of the upper electrode may be performed through an electron beam deposition process with an electrode precursor input.

As described above, the embodiment has an active layer capable of multiple conductive filaments provided through the growth of a metal oxide thin film and metal nanoparticles, and through this, uniformity and multiplicity can be satisfied at the same time, and individually operable filament-type behavior that enables gradual analog switching and synaptic operation can be induced.

In addition, in the case of the resistance change memory manufacturing process according to the embodiment, there is an advantage in that a formation region of a conductive filament can be fixed from the stage before the formation of the conductive filament when a resistance change is driven by metal nanoparticles grown through electrochemical pulse deposition, and a process of generating the conductive filament can be confirmed as an in-situ process.

In contrast to most of the existing studies which grow an active layer through a physical vapor deposition process including an atomic layer thin film process, thus requiring expensive equipment is required to control high temperature and vacuum conditions,
the growth of an active layer through an electrochemical method according to an embodiment of the disclosure can significantly reduce the process cost because low-cost equipment is used.

Hereinafter, a resistance change memory according to another embodiment of the disclosure will be described.

As an example of the embodiment, there may be a resistance change memory, which is manufactured according to the method described above, including: a lower electrode; an active layer positioned on the lower electrode; and an upper electrode positioned on the active layer, wherein the active layer has multiple conductive filaments uniformly formed.

At this time, the active layer may include: a first metal oxide thin film layer; a metal nanoparticle layer positioned on the first metal oxide thin film layer; and a second metal oxide thin film layer positioned on the metal nanoparticle layer.

Referring to FIG. 2, it is possible to confirm an example of the embodiment, in which a resistance change memory manufactured through the above-described method includes: a lower electrode 100; a first metal oxide thin film layer 200 positioned on the lower electrode; a metal nanoparticle layer 300 positioned on the first metal oxide thin film layer; a second metal oxide thin film layer 400 positioned on the metal nanoparticle layer; and an upper electrode 500 positioned on the active layer.

As an example of the embodiment, the active layer may be formed to have a thickness range of 600 nm or less (=total thickness range of the first metal oxide thin film layer, the metal nanoparticle layer, and the second metal oxide thin film layer).

In addition, the metal nanoparticle layer may include metal nanoparticles having a diameter of 10 nm to 100 nm.

At this time, the metal nanoparticle layer does not have to be formed in the form of a film or thin film, and may be more preferable to be deposited in the form of particles rather than in the form of a thin film. In addition, it may refer to the region itself where the metal nanoparticles are distributed and present.

Therefore, in the resistance change memory according to an example of the embodiment,
the active layer may be a structure in which a region where a large number of the metal nanoparticles are distributed exists inside the metal oxide thin film layer (referring to both the first metal oxide thin film layer and the second metal oxide thin film layer).

At this time, in order for the metal nanoparticles to exist inside the metal oxide thin film layer, the active layer must basically be formed with a thickness greater than the diameter of the metal nanoparticles.

When the thickness of the active layer exceeds 600 nm, a conductive filament is formed and the charge transfer path from the upper/lower electrode to the lower/upper electrode becomes longer, so a high applied voltage is required. This poses a challenge to reasonable memory device performance targeting low power operation and low applied voltage.

In addition, as described above, in order for the metal nanoparticles to exist inside the metal oxide thin film layer, the active layer must basically be formed with a thickness greater than the diameter of the metal nanoparticles.

If the diameter of the metal nanoparticles is less than 10 nm, there is a problem that the conductive filaments do not have a uniform spherical shape but exist as irregularly shaped nanoparticles.

On the other hand, even if the diameter of the metal nanoparticles exceeds the critical point of 100 nm, irregularly shaped nanoparticles are generated and a gap between the metal nanoparticles is very narrow, which causes problems of interference between particles in the formation of conductive filaments and charge behavior.

In addition, if the diameter of the metal nanoparticles exceeds 100 nm, overlap occurs between the metal nanoparticles, and they grow in the form of a metal thin film rather than a particle form, which leads to a result contrary to the purpose of the disclosure to form multiple strong filaments.

In contrast to the above, when the diameter of the metal nanoparticles has a thickness range of 10 nm to 100 nm, the conductive filament has a uniform spherical shape, and a gap between the first and second metal oxide thin film layers formed by each metal nanoparticle having the above diameter range has an advantage of having a shape suitable for realizing multiple filaments.

### Manufacturing Example 1. Manufacturing a Resistance Change Memory (ITO/Cu₂O/Cu/Cu₂O/Pt) According to the Embodiment

1. An ITO lower electrode is prepared (S100).
2. CuSO₄ 0.4M is dissolved in lactic acid 3M based on 200 ml of DI water as a solvent to form an electrochemical deposition solution.
3. Thereafter, Sb₂(SO₄)₃ mM and Pb(C₂H₃O₂)₄ 3 mM as metal additives are dissolved in the deposition solution.
4. The lower electrode is impregnated in the formed solution (S210), and a first voltage (−0.4 V) is applied to form a Cu₂O thin film layer through an electrochemical pulse deposition process. (S220)
5. In the same solution, a second voltage (−1 V) is applied to form a Cu nanoparticle layer through an electrochemical pulse deposition process. (S310)
6. In the same solution, a third voltage (−0.4 V) is applied to form a Cu₂O thin film layer through an electrochemical pulse deposition process. (S410)
7. A Pt upper electrode is formed using an electron beam deposition device that has a Pt target. (S510)

### Experimental Example 1. Experiments on the Desired Potential Range of the Applied Voltage

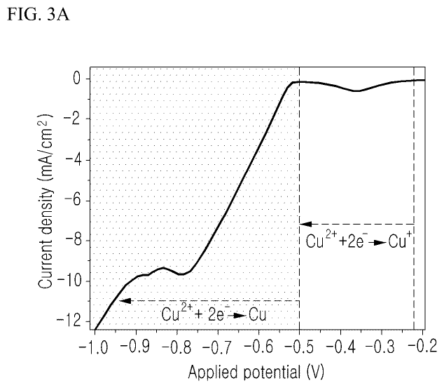

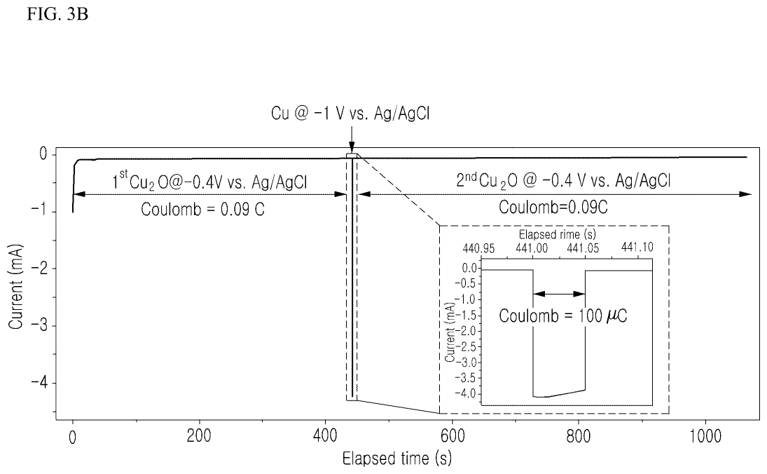

FIG. 3A shows a voltage-current graph when inducing an electrochemical oxidation reaction for forming Cu₂O thin film and Cu nanoparticles, which constitute the active layer in a device, in an electrolyte containing a metal precursor for manufacturing an active layer based on copper oxide, and

FIG. 3B is a graph showing the change in current over time during the electrochemical growth of the thin film and nanoparticles.

When the oxidation/reduction reaction is induced in an electrolyte containing a Cu precursor,
referring to FIG. 3A, it is possible to confirm that divalent Cu ions are reduced to monovalent Cu ions in a potential range of −0.2 V to −0.5 V, and
that divalent Cu ions are reduced to Cu metal in a potential range below −0.5 V, resulting in a current drop.

Therefore, independent deposition potentials of the Cu₂O thin film and Cu nanoparticles are specified.

Finally, Cu nanoparticles can be induced by changing the applied voltage instantaneously, which means that Cu₂O thin film and Cu metal constituting the active layer can be continuously produced by changing the applied voltage in the same electrolyte.

Therefore, a Cu₂O thin film of 200 nm to 300 nm is generated in the potential range of −0.2 V to −0.5 V, and
Cu nanoparticles are grown for a short pulse time of less than 1 second by moving to −2 V to −0.5 V.

Afterwards, a Cu₂O thin film of 200 nm to 300 nm is generated again in the potential range of −0.2 V to −0.5 V, and the Cu₂O thin film and Cu nanoparticles required for the active layer are confirmed by an in-situ process.

At this time, in the process of growing the Cu nanoparticles, the voltage in the range of −2 V to −0.5 V is applied for a short pulse time of less than 1 second, wherein
if the voltage is applied for more than 1 second, which is the critical point, the growth of Cu nanoparticles occurs continuously, and metal nanoparticles having a thickness of 100 nm or more are grown. If metal nanoparticles with a large thickness and size of the thin film grow, there may be a negative effect on the charge behavior when forming a conductive filament, which is disadvantageous for the formation of multiple filaments.

### Experimental Example 2. Performance Analysis According to the Active Layer Structure of Resistance Change Memory

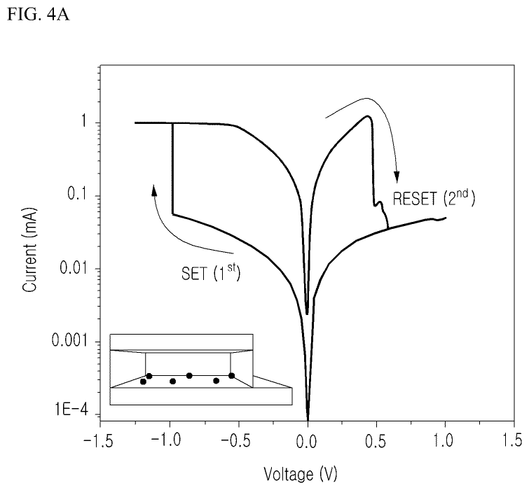

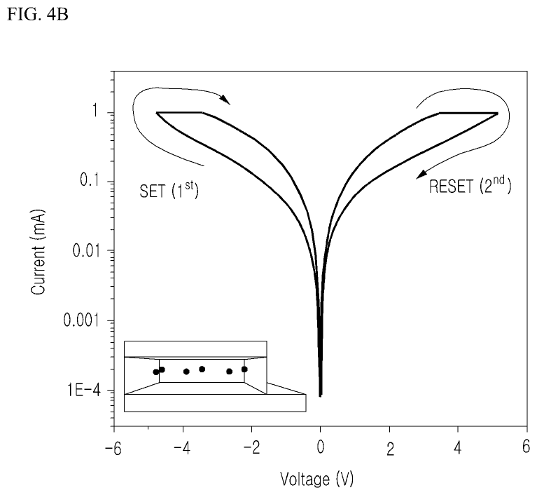

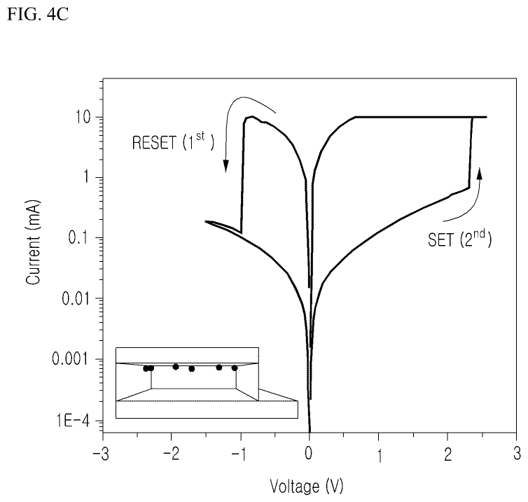

FIGS. 4A, 4B, and 4C show electrical current-voltage graphs of each device after dividing the deposition section of Cu nanoparticles in a Cu₂O thin film forming an active layer into the (A) upper part, (B) center, and (C) lower part regions.

Since Cu₂O thin films and Cu nanoparticles are grown via electrochemical pulse deposition, the thickness of the thin film and the size of the particles may be controlled in-situ by varying the pulse conditions.

Furthermore, the position may also be controlled by controlling the pulse conditions and order of the nanoparticles.

Referring to FIG. 4A, it is possible to confirm that when the Cu nanoparticles are grown on the lower part of the Cu₂O thin film, the applied electric field is concentrated on the metallic Cu particles, and thus conductive filaments are easily formed at a low voltage, but that
only the driving voltage is reduced without help for filament formation, and there is a rapid current change and no suitability for analog switching for synaptic behavior.

Referring to FIG. 4B, when the Cu nanoparticles are grown on the central part of the Cu₂O thin film, it is possible to confirm that this has symmetrical bipolar switching characteristics and has a progressively excellent analog switching operation even in the Set/Reset process.

In addition, this shows a special driving mechanism similar to the apparatus with multiple multi-conductive filaments, which is the aspect of the disclosure.

Referring to FIG. 4C, when the Cu nanoparticles are grown on the upper part of the Cu₂O thin film, the Cu nanoparticles grow on the surface region of Cu₂O, which has higher conductivity.

This becomes the path of the conductive filaments in the switching operation, but the HRS current is higher and the On/Off ratio is significantly lower, which deteriorates the memory performance.

Ultimately, when the nano Cu nanoparticles are in the center of the Cu₂O thin film, they receive a concentrated high electric field more than other regions and act as an active region for resistance switching.

Therefore, it can be seen that the nanoparticles reasonably controlled through the electrochemical pulse act as a path of uniform multi-conductive filaments for the resistance switching operation, which is the aspect of the disclosure.

### Experimental Example 3. Image Analysis of Resistance Change Memory According to the Amount of Cu Nanoparticles

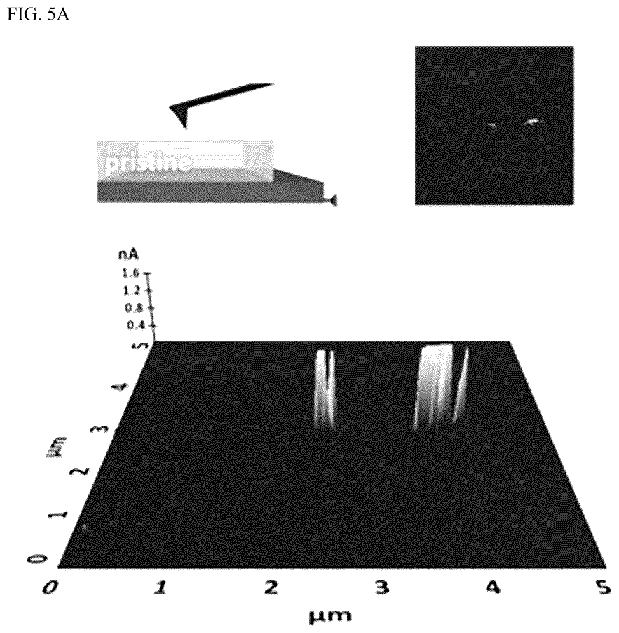

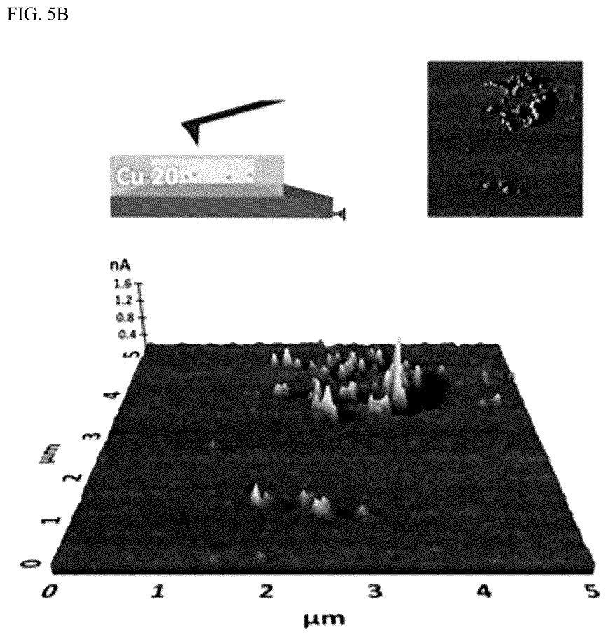

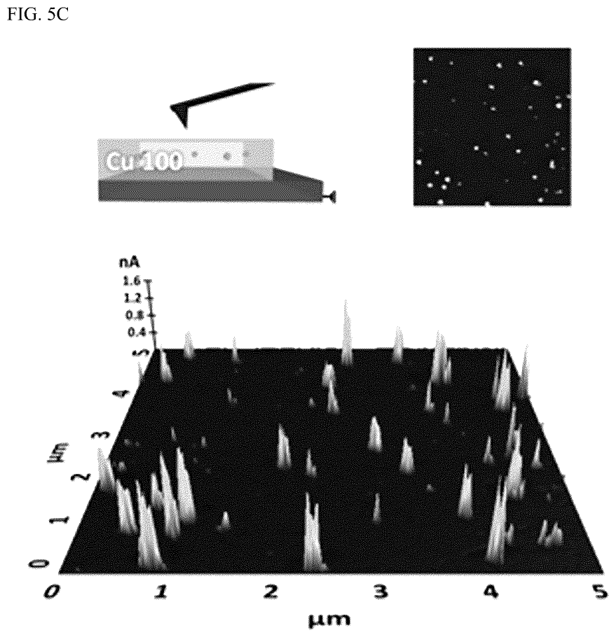

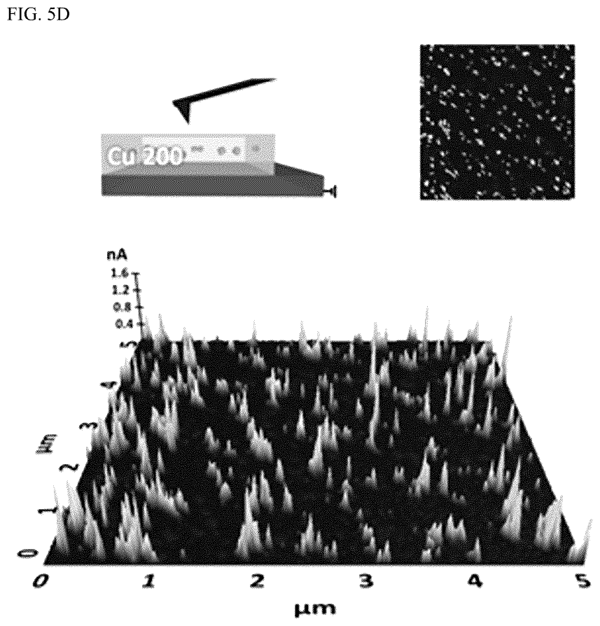

FIGS. 5A, 5B, 5C, and 5D are images of the results of conductivity-atomic force microscopy analysis of a device manufactured after controlling the amount of Cu nanoparticles in manufacturing a resistance change memory according to an embodiment of the disclosure.

(The results were obtained through conductivity-atomic force microscopy analysis of the device with the upper electrode removed after setting it to the LRS state in the voltage application scheme.)

At this time, the size of Cu nanoparticles in the active layer based on Cu₂O thin film was compared to the Pristine state, 20, 100, and 200 by changing the electrochemical pulse deposition conditions.

In the above Cu 20, Cu 100, and Cu 200, the numbers mean the Coulomb (C) value, which is the amount of electricity flowing through the device during the electrochemical pulse deposition process.

As shown in the inset diagram in FIG. 3B, the Pristine state is a state without metal nanoparticles, and Cu 20, Cu 100, and Cu 200 respectively means states in which −20 μC, −100 μC, and −200 μC were applied in the electrochemical pulse deposition process.

In FIGS. 5A, 5B, 5C, and 5D, the protrusions can be seen as numerous sites that may concentrate an external electric field that may create a conductive filament path.

That is, it indicates the location of the conductive filament in relation to the occurrence of a locally concentrated electric field.

Referring to FIGS. 5A, 5B, 5C, and 5D, it was confirmed that the Pristine without Cu nanoparticles had a strong single conductive filament. In contrast, the width of the filament gradually decreased as the amount of Cu nanoparticles deposited increased.

In addition, it was confirmed that the conductive filaments of the Cu 100 and Cu 200 devices increased dramatically compared to the Cu 20 device.

In the case of Cu 200, which has the densest protrusions, the conductive portions evenly occupy a large region in the LRS, which is similar to the behavior of the interface type mentioned above.

The results of the analysis show that the Cu 100 device with dispersed protrusions may generate the most uniform and appropriate multi-filaments through control by electrochemical pulse deposition. This means that Cu nanoparticles act as a functional sub-layer capable of uniformly distributing multiple conductive filaments.

As a result, it is possible to confirm that the device having a Cu₂O thin film active layer in which Cu nanoparticles exist in the disclosure may fix the conductive filament formation region from the stage before the formation of the conductive filaments when driving the resistance change.

### Experimental Example 4. Analysis of the Results of the Evaluation of the Characteristics of Resistance Change Memory According to the Embodiment

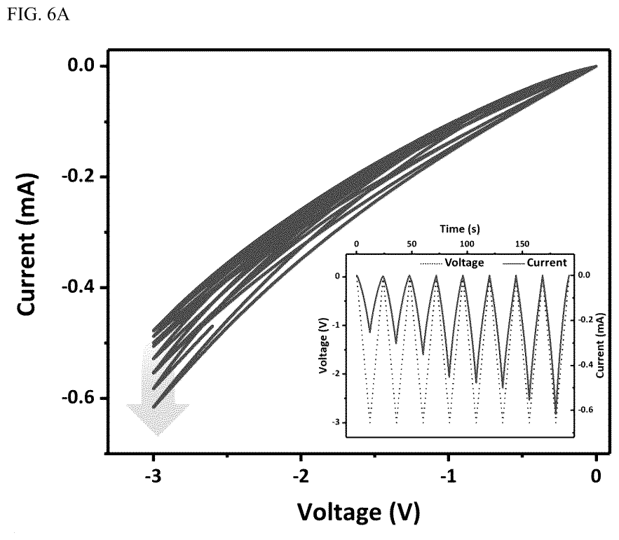

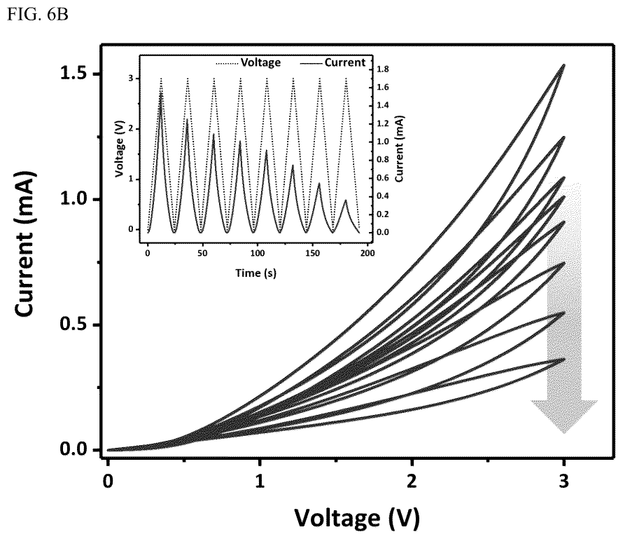

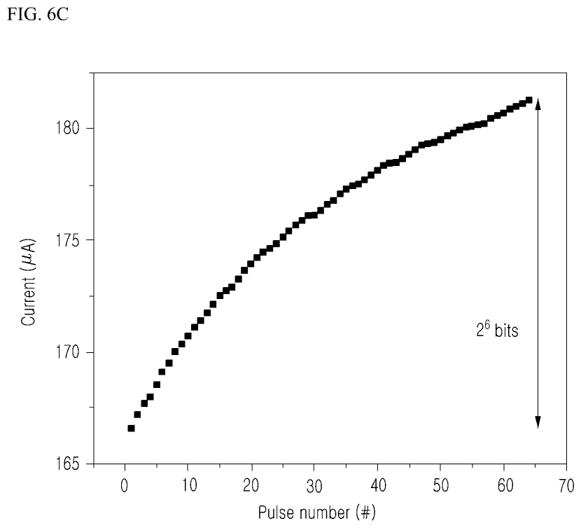

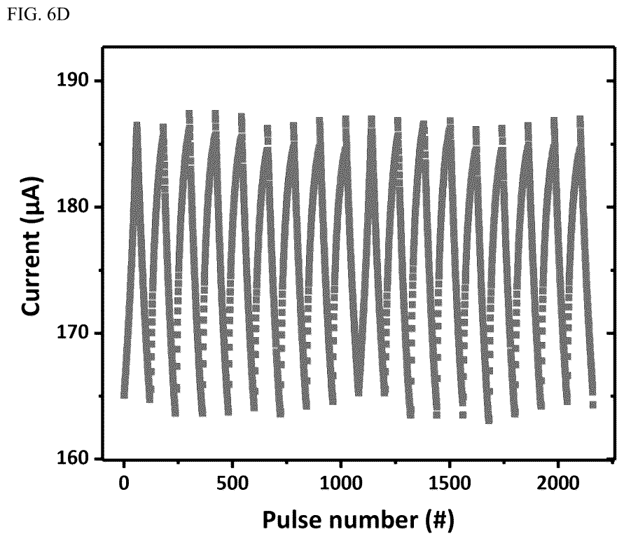

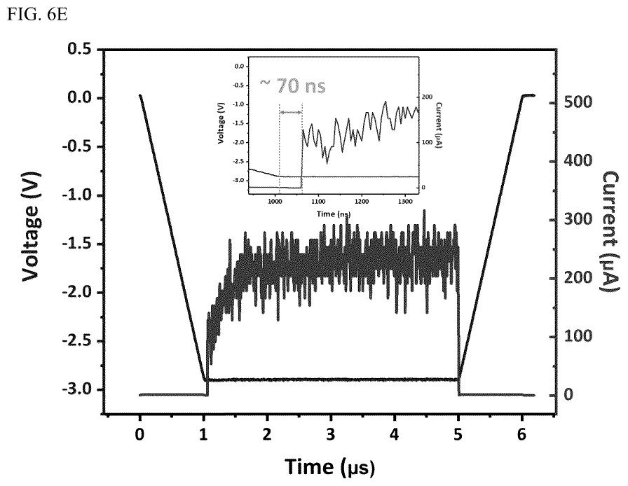

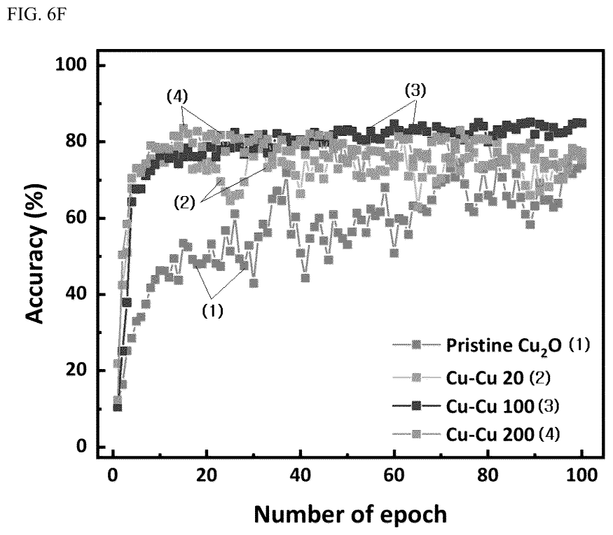

FIGS. 6A, 6B, 6C, 6D, 6E, and 6F are graphs showing the results of evaluating the synaptic device characteristics of a resistance change memory (ITO/Cu₂O/Cu/Cu₂O/Pt) according to an embodiment of the disclosure.

Optimal characteristics for neuromorphic computing were achieved simultaneously through uniform multi-conductive filaments.

In FIG. 6A, a gradual increase in current was observed during 8 LRS switching cycles by repeating continuous negative voltage sweeps from 0 V to −3 V.

In contrast, in FIG. 6B, 8 HRS switching cycles were secured by repeating positive voltage sweeps from 0 to 3 and then back to 0 V.

In the diagrams inserted in FIGS. 6A and 6B, voltage and current data are sequentially displayed over time, and gradual conductivity changes can be clearly observed. Through this, it can be seen that the resistance change memory device according to the embodiment of the disclosure may stably store multi-stage outputs similar to analog characteristics in which gradual increases or decreases in current are prominent.

In FIG. 6C, it is possible to confirm that one reinforcement/suppression cycle has more than 64 levels. The precision of the device indicates how many resistance levels are accessible across the entire dynamic range, and at least 16 levels are required for stable device operation. Through this, it can be seen that the resistance change memory device according to the embodiment of the disclosure is advantageous for training efficiency and recognition accuracy.

In FIG. 6D, it is possible to confirm that the durability may be evaluated for the uniformity between cycles for the synaptic learning behavior corresponding to reinforcement/suppression, and the linearity, symmetry, and dynamic range are maintained with less than 2% conduction degradation for 20 learning cycles. Through this, it can be seen that the device has stable durability for device operation.

In FIG. 6E, a pulse measurement apparatus was applied to measure the programming speed. When providing a bias spike input of −3 V, the programming speed for reinforcement was presented. Through this, it was confirmed that the resistance state may be switched within 70 ns after applying the programming bias spike.

In FIG. 6F, it is possible to confirm the accuracy for identifying the synapse performance of the resistance change memory device according to the embodiment of the disclosure, and it can be seen that the Cu—Cu 100 device with high linearity and high symmetry due to the multi-conductive filaments achieved the highest recognition rate (85.17%) as a high-performance neuromorphic computing engine.

In the case of the synapse device of the resistance change memory (ITO/Cu₂O/Cu/Cu₂O/Pt) according to an embodiment of the disclosure, it was confirmed that this is a memory device capable of high efficiency/low power operation compared to a resistance-based synapse device having a similar structure including an active layer and a metal electrode.

The description of the disclosure is for illustrative purposes, and those skilled in the art will understand that it can be easily modified into other specific forms without changing the technical idea or essential features of the disclosure. Therefore, the embodiments described above should be understood as being exemplary in all respects and not limiting. For example, each component described as a single type may be implemented in a distributed manner, and likewise, components described as distributed may be implemented in a combined form.

The scope of the disclosure is indicated by the following claims, and all changes or modifications derived from the meaning and scope of the claims and their equivalent concepts should be interpreted as being included in the scope of the disclosure.

### EXPLANATION OF REFERENCE NUMERALS

100: lower electrode
200: first metal oxide thin film layer
300: metal nanoparticle layer
400: second metal oxide thin film layer
500: upper electrode

What is claimed is:

1. A method for manufacturing a resistance change memory, the method comprising forming an active layer between a lower electrode and an upper electrode, wherein the active layer comprises a metal oxide thin film and metal nanoparticles, and the forming of the active layer is performed by an electrochemical reaction process.

2. The method of claim 1, wherein in the forming of the active layer, the active layer is formed so that multiple conductive filaments are uniformly formed through an electrochemical pulse deposition process.

3. The method of claim 1, wherein the forming of the active layer comprises:
forming a first metal oxide thin film layer;
forming a metal nanoparticle layer on the formed first metal oxide thin film layer; and
forming a second metal oxide thin film layer on the formed metal nanoparticle layer.

4. The method of claim 3, wherein the forming of the first metal oxide thin film layer comprises:
impregnating the lower electrode in a solution comprising a metal oxide precursor and an electrolyte; and
applying a first voltage to the solution.

5. The method of claim 4, wherein the forming of the metal nanoparticle layer is performed, after the applying of the first voltage, by applying a second voltage to the solution.

6. The method of claim 5, wherein the forming of the second metal oxide thin film layer is performed, after the applying of the second voltage, by applying a third voltage to the solution.

7. The method of claim 4, wherein in the applying of the first voltage,
a voltage of −0.5 V to −0.2 V is applied.

8. The method of claim 5, wherein in the applying of the second voltage,
a voltage of less than −0.5V is applied.

9. The method of claim 6, wherein in the applying of the third voltage,
a voltage of −0.5 V to −0.2 V is applied.

10. The method of claim 1, wherein the metal oxide thin film and metal nanoparticles are composed of at least one metal selected from the group consisting of Cu, Ti, Zr, Pb, Mn, Bi, Al, Sb, Fe, Co, Nb, and Cr.

11. The method of claim 1, further comprising after the forming of the active layer, forming an upper electrode on the formed active layer.

12. The method of claim 11, wherein the forming of the upper electrode is performed through an electron beam deposition process with an electrode precursor input.

13. A resistance change memory, which is manufactured according to claim 1, comprising:
a lower electrode;
an active layer positioned on the lower electrode; and
an upper electrode positioned on the active layer,
wherein the active layer has multiple conductive filaments uniformly formed.

14. The resistance change memory of claim 13, wherein the active layer comprises:
a first metal oxide thin film layer;
a metal nanoparticle layer positioned on the first metal oxide thin film layer; and
a second metal oxide thin film layer positioned on the metal nanoparticle layer.

15. The resistance change memory of claim 14, wherein the metal nanoparticle layer comprises metal nanoparticles having diameters of 10 nm to 100 nm.
